(19) United States
(12) Patent Application Publication
(10) Pub. No.: US 2025/0149326 A1
(43) Pub. Date: May 8, 2025

(54) Method and System for Torsional Optical Manipulation to Remove Particles from Semiconductor Surfaces

(71) Applicants: Chun-Jung Chiu, New Taipei City (TW); Chun-Hsiung Chen, New Taipei City (TW); Wan-Chen Chuang, New Taipei City (TW)

(72) Inventors: Chun-Jung Chiu, New Taipei City (TW); Chun-Hsiung Chen, New Taipei City (TW); Wan-Chen Chuang, New Taipei City (TW)

(21) Appl. No.: 19/018,889

(22) Filed: Jan. 13, 2025

Related U.S. Application Data
(63) Continuation-in-part of application No. 17/979,795, filed on Nov. 3, 2022, now Pat. No. 12,214,385.

(30) Foreign Application Priority Data
Nov. 5, 2021 (TW) 110141279

(51) Int. Cl. H01L 21/02; B08B 7/00; B81C 1/00; G03F 1/82; H01L 21/67

(52) U.S. Cl. CPC H01L 21/02098; B08B 7/0042; B81C 1/00841; G03F 1/82; H01L 21/67288

(57) ABSTRACT

A method and system for effectively removing particles from semiconductor surfaces using a multi-beam laser-based approach. The invention employs a plurality of laser beams generated by a spatial light modulator, which create multiple light spots on a particle at various locations across its surface. By adjusting the phase of these laser beams, alternating clockwise and counterclockwise torsional forces are induced, generating rotational movement that weakens the adhesion between the particles and the semiconductor surface. The system utilizes a liquid crystal spatial light modulator to precisely control beam parameters, enhancing the ability to reduce adhesion forces due to van der Waals interactions or electrostatic forces. An automated optical inspection system provides real-time monitoring and feedback, ensuring precise manipulation and complete removal of particles. An airstream is subsequently employed to detach and remove the loosened particles, thereby improving semiconductor surface cleanliness without causing mechanical damage.

### TECHNICAL FIELD

The present disclosure is related to a method for cleaning semiconductor process equipment and a system thereof, more particularly to the method and system to eliminate contaminants/particles of the semiconductor process equipment.

### BACKGROUND

In semiconductor manufacturing processes, maintaining clean surfaces is essential to ensuring product quality and performance. Particles and contaminants on semiconductor surfaces, such as photomasks or other process-critical equipment, can lead to defects, yield loss, and compromised functionality of semiconductor devices. As semiconductor technology advances and feature sizes become smaller, the removal of these particles has become increasingly challenging, necessitating improved cleaning methods that address adhesion in dry, non-liquid environments.

Traditional approaches to particle removal, such as single-beam laser-based optical tweezers, have been explored to manipulate and remove particles. These methods, such as the one disclosed in TSMC's patent U.S. Pat. No. 11,145,427B2, involve the use of a single focused laser beam to generate forces that push or pull particles from surfaces. While these techniques can be effective under certain conditions, they face significant limitations when applied to dry environments typical in semiconductor manufacturing. In particular, the adhesion forces between particles and surfaces in these conditions are much stronger compared to liquid environments, making single-beam manipulation insufficient for effective detachment.

TSMC's approach, while novel in utilizing optical tweezers to address particle contamination, is primarily effective in environments where the adhesion force is relatively weak, such as in liquid mediums or for larger particles that do not require complex manipulation to detach. However, in dry environments, single-beam methods often fail to generate the force necessary to overcome the strong particle-to-surface adhesion, particularly for submicron particles that adhere via van der Waals forces or electrostatic forces.

Despite advancements in particle removal technologies, there remains a need for an effective solution specifically designed for dry semiconductor manufacturing environments. Conventional single-beam optical tweezers, while effective in certain liquid-based applications, face challenges in overcoming strong adhesion forces in dry conditions. These forces are typically caused by van der Waals forces or electrostatic forces, which are not easily mitigated with traditional linear force methods.

Other particle removal methods, such as ultrasonic or mechanical brushing, have also been employed but tend to introduce potential damage to sensitive surfaces or fail to adequately address submicron particles. There is therefore a pressing need for non-contact, precise particle manipulation techniques that can effectively mitigate these strong adhesion forces without compromising the integrity of semiconductor equipment.

Furthermore, ensuring the thorough removal of contaminants without causing recontamination is critical to maintaining the performance of semiconductor devices. Effective solutions should ideally integrate real-time monitoring to accurately detect and locate particles during the removal process, thereby minimizing the risk of residue or incomplete cleaning. Addressing these challenges requires an innovative approach that combines precision, adaptability, and non-contact manipulation suitable for the increasingly complex requirements of modern semiconductor manufacturing.

### SUMMARY

The present disclosure provides a method and system for effectively removing particles from semiconductor surfaces by employing an innovative multi-beam laser-based approach designed for dry environments. The invention utilizes a plurality of laser beams, generated and modulated by a spatial light modulator, to create multiple light spots on a target particle at different locations across its surface. By adjusting the phase of these beams, the invention generates alternating clockwise and counterclockwise torsional forces that induce rotational movement of the particles. This torsional manipulation effectively weakens the adhesion forces between the particles and the semiconductor surface, ultimately facilitating easier removal.

In one aspect of the invention, a liquid crystal spatial light modulator (LCSLM) is used to control the phase, intensity, and direction of the laser beams, allowing precise adjustment of the forces applied to each particle. By synchronizing these parameters, the system achieves controlled twisting of particles, thereby reducing adhesion that results from van der Waals forces or electrostatic forces. The rotational forces generated by the multiple beams provide a more effective means of weakening adhesion compared to traditional linear pushing methods.

Another aspect of the invention includes a feedback system using Automated Optical Inspection (AOI). The AOI system continuously monitors the position and status of the particles on the semiconductor surface, providing real-time feedback that enables adaptive adjustments to the laser beams as needed to achieve optimal detachment conditions. Once the particles are sufficiently loosened, an airstream is directed at the surface to remove the particles entirely, preventing recontamination.

The present disclosure is particularly suited for semiconductor manufacturing processes where particles must be removed from delicate surfaces, such as photomasks and wafers, without causing mechanical damage. The combination of multi-beam laser-induced torsional manipulation and real-time feedback control represents a significant advancement over existing cleaning techniques, offering improved efficiency and effectiveness in dry, high-adhesion environments.

Accordingly, it is an object of the present disclosure to provide a non-contact particle removal method that utilizes torsional forces to effectively detach particles from semiconductor surfaces.

It is a further object of the invention to provide a system for real-time monitoring and feedback control to ensure precision and completeness of the cleaning process.

Another object of the invention is to minimize the potential for damage to sensitive semiconductor surfaces during the particle removal process, while ensuring that even submicron particles are effectively loosened and removed.

These and other objects, features, and advantages of the present disclosure will become more apparent from the following detailed description, taken in conjunction with the accompanying drawings and claims.

### BRIEF DESCRIPTION OF THE DRAWINGS

The objects, features, and advantages of the embodiments of the present disclosure will be readily understood by the accompanying drawings and detailed descriptions, wherein:

FIG. 1 illustrates a schematic block diagram of an embodiment of a system of the present disclosure for removing particles from semiconductor surfaces;

FIG. 2 illustrates a schematic view of the surface of a particle in this embodiment.

FIG. 3 illustrates an airflow generation unit generating an airflow to the semiconductor surface.

FIG. 4 illustrates a flowchart of an embodiment of the cleaning method described in the present disclosure.

### DETAILED DESCRIPTION

The present disclosure is directed towards an advanced cleaning system designed specifically for the effective removal of particles from semiconductor surfaces in dry, high-adhesion environments. The system combines multiple laser beams, generated by a spatial light modulator, with a feedback-driven automated control mechanism to induce torsional forces on target particles. These torsional forces, created through alternating clockwise and counterclockwise movements, work to effectively weaken the adhesion forces binding particles to the surface, enabling their efficient removal without causing damage to sensitive semiconductor components.

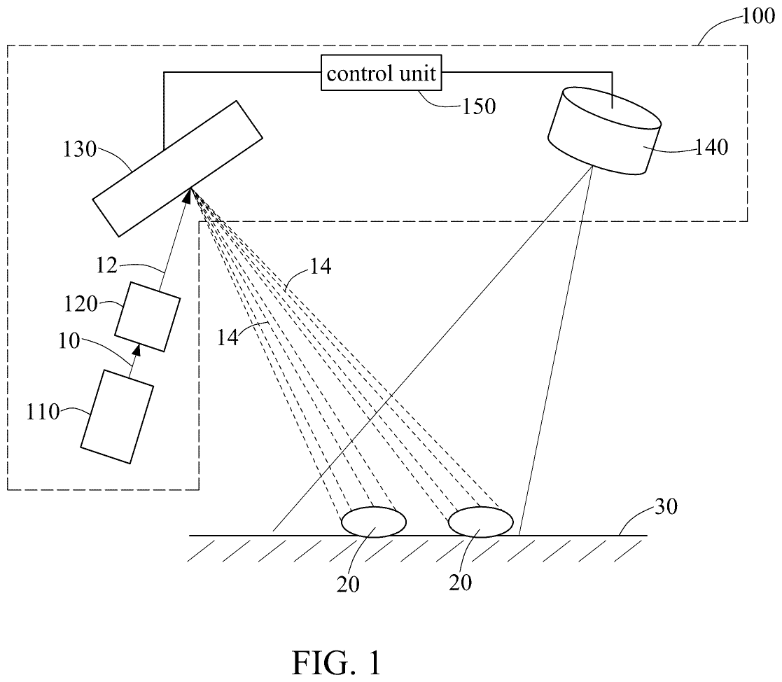

Refer to FIG. 1, which illustrates a schematic block diagram of an embodiment of a system for removing particles from semiconductor surfaces, as disclosed herein. The system 100 comprises several key components that work in tandem to achieve the desired effect of particle removal. These components include a laser source 110, a beam expander 120, a spatial light modulator 130, an AOI system (Automated Optical Inspection system) 140, and a control unit 150. The laser source 110 is responsible for emitting a coherent laser beam 10 that serves as the basis for the multiple optical tweezers used to manipulate particles. The emitted laser beam 10 is then expanded and modulated by subsequent components to generate multiple distinct beams. The beam expander 120 is used to widen the initial laser beam 10 before it is further processed. Expanding the laser beam 10 helps in creating the multiple light spots needed for generating torsional forces on particles 20.

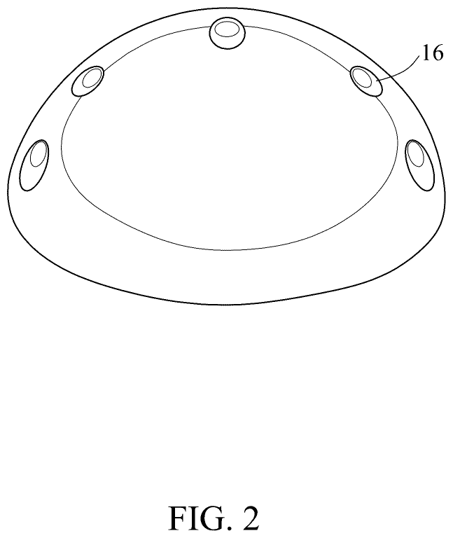

Please refer simultaneously to FIG. 2, which illustrates a schematic view of the surface of a particle in this embodiment. The spatial light modulator 130, specifically a liquid crystal spatial light modulator, is used to divide the expanded laser beam 12 into a plurality of individually controllable laser beams 14. Each laser beam 14 is directed to create a corresponding light spot 16 on the surface of the particle 20. The spatial light modulator 130 controls the phase, intensity, and direction of each laser beam 14, enabling the precise application of forces at multiple points across the particle 20.

The system 100 operates using optical tweezers, which are formed by focusing laser beams 14 on specific points to create the corresponding light spot 16. In this invention, multiple optical tweezers are generated simultaneously, each targeting a different location on a single particle 20's surface. These optical tweezers create localized forces that are essential for generating the required torsional effect. The AOI system 140 provides critical real-time monitoring of particles 20 on the semiconductor surface 30. It identifies the presence, position, and movement of particles 20 and provides feedback to the control unit 150. This feedback is used to dynamically adjust the parameters of the laser beams 14 to ensure optimal detachment and removal conditions. The control unit 150 manages the overall coordination of the system 100. It receives input from the AOI system 140 and uses it to adjust the phase, intensity, and angle of the laser beams 14 via the spatial light modulator 130. This enables adaptive control to address variations in particle size, adhesion strength, and surface characteristics, ensuring effective and consistent particle removal.

The AOI system 140 is an optical monitoring solution that is responsible for continuously inspecting the semiconductor surface 30 to detect particles 20 and monitor their status throughout the cleaning process. The AOI system 140 uses high-resolution imaging sensors, such as CCD (Charge-Coupled Device) or CMOS (Complementary Metal-Oxide-Semiconductor) cameras, to capture real-time images of the semiconductor surface 30. These images are then analyzed to determine the precise position, orientation, and movement of particles on the surface.

The data obtained by the AOI system 140 serves as the foundation for the feedback loop, allowing the system 100 to adapt in real-time to changing conditions during the cleaning process. By providing detailed information on the position and characteristics of each particle 20, the AOI system 140 enables the control unit 150 to make informed decisions about how best to adjust the laser beams for optimal detachment.

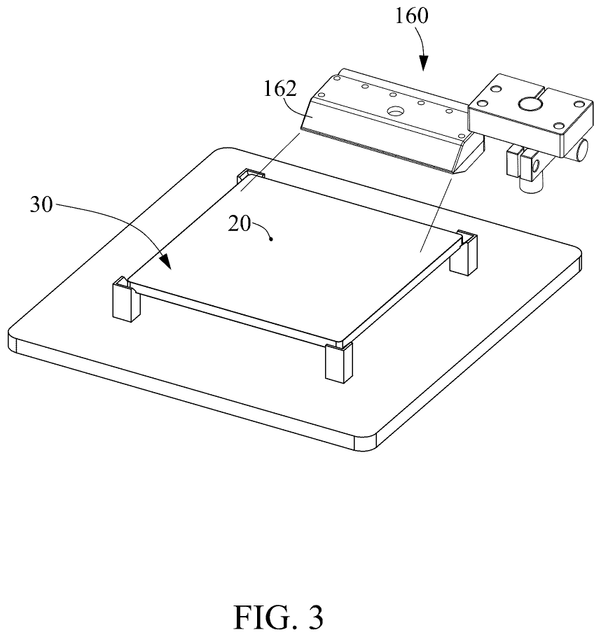

Please refer simultaneously to FIG. 3, which illustrates an airflow generation unit generating an airflow to the semiconductor surface. Once the adhesion between the particle 20 and the semiconductor surface 30 has been sufficiently weakened by the torsional forces, an airflow generation unit 160 (such as an air knife or blower) is used to produce a controlled airstream. This airstream physically removes the loosened particles 20 from the semiconductor surface 30, preventing re-adhesion and ensuring a clean working environment.

The present disclosure leverages advanced laser beam modulation techniques to achieve effective particle removal from semiconductor surface 30. This following content describes in detail how laser beams are generated, expanded, divided, and modulated to facilitate the desired torsional forces on the particles, ensuring efficient detachment.

The system 100 begins with a laser source 110 capable of emitting a coherent laser beam 10 at a wavelength suitable for effective manipulation of particles 20. The laser beam 10 is first directed into the beam expander 120. The purpose of the beam expander 120 is to broaden the diameter of the laser beam 12, making it possible to subsequently divide the laser beam 12 into multiple smaller beams 14, each capable of focusing on different locations on the particle 20. The expansion of the laser beam 12 also ensures that each resulting beam 14 possesses adequate power density to generate optical tweezers capable of inducing torsional forces.

Once expanded, the laser beam 12 is passed through a spatial light modulator 130, specifically a liquid crystal spatial light modulator. The spatial light modulator 130 is a key component in the system 100, as it is responsible for dividing the expanded laser beam 12 into a plurality of individually controllable beams 14. Each beam 14 produced by the spatial light modulator 130 can be modulated in terms of its phase, intensity, and direction, making it possible to target multiple specific points on a particle.

The spatial light modulator 130 is programmed to create multiple light spots 16 on the target particle 20, each positioned at a different point across the particle 20's surface. By having control over the phase of each beam 14, the system can create alternating clockwise and counterclockwise movements, generating torsional forces. These forces effectively weaken the adhesion forces between the particle 20 and the semiconductor surface 30, making removal much more efficient.

The core of the system 100's ability to detach particles lies in the phase modulation of the laser beams. By adjusting the relative phase between the beams 14, it is possible to create torsional forces that rotate the particle in place. This is achieved through a coordinated modulation of the beams 14, with some beams 14 being advanced in phase while others are delayed, resulting in a twisting effect.

The phase-shift technique allows the system 100 to alternate between clockwise and counterclockwise rotational forces. This back-and-forth twisting movement helps in overcoming the various adhesion forces, such as van der Waals forces or electrostatic forces, which often bind particles to the surface. By cyclically altering the direction of rotation, the particles 20 are gradually loosened without causing any damage to the underlying semiconductor surface 30.

While phase modulation is primarily used to generate torsional forces, intensity and angle modulation of the laser beams are also employed to optimize the detachment process. The intensity of each beam 14 can be adjusted to ensure that sufficient force is applied to the particle 20 without exceeding thresholds that could cause damage to the semiconductor surface 30. Similarly, the angle of incidence of each beam 14 can be modulated to ensure that the generated forces are optimally aligned with the surface of the particle 20, maximizing the efficiency of the torsional effect.

The combination of phase, intensity, and angle modulation allows for precise control over the manipulation forces exerted on the particles 20. This level of control is crucial for adapting to variations in particle size, shape, and adhesion strength, providing a versatile solution for a wide range of cleaning scenarios.

In addition, the effective operation of the system 100 requires that the multiple beams generated by the spatial light modulator 130 be carefully synchronized. The control unit 150, which receives feedback from the AOI system 140, plays a key role in maintaining this synchronization. The AOI system 140 continuously monitors the position and status of the particles, and the control unit 150 uses this information to adjust the phase, intensity, and angle of each beam in real time.

The synchronization of the beams 14 ensures that the torsional forces are applied in a manner that maximizes their effectiveness. By coordinating the phase shifts and ensuring that the twisting forces are applied uniformly across the particle 20, the system 100 prevents the particle 20 from shifting unpredictably or remaining attached in an uneven manner. This precise application of torsional forces is essential for achieving complete detachment without causing damage.

The key to the system 100's effectiveness in removing particles 20 lies in the concept of torsional force generation. By directing multiple laser beams onto a particle 20, each beam 14 produces a localized force at a specific point on the particle 20's surface. When these beams are modulated with appropriate phase shifts, the resulting forces work together to create a rotational effect. The beams 14 are directed in such a way that some forces induce clockwise rotation while others induce counterclockwise rotation, thereby generating alternating torsional movement.

The alternating torsional movement generated by the beams 14 is crucial for weakening the adhesion forces between the particle and the semiconductor surface. Unlike traditional linear forces, which push or pull particles in a single direction, torsional forces rotate the particle 20, creating a dynamic shearing effect. This shearing effect is particularly effective at overcoming the van der Waals forces or electrostatic forces that typically bind particles to surfaces in dry environments.

To create the torsional forces, the control unit 150 adjusts the phase of each laser beam. By precisely synchronizing the phase shifts, the beams 14 can be modulated to generate clockwise and counterclockwise rotations in a controlled manner. This rotational movement alternates between directions, which serves several important purposes. For example, the alternating rotations work to break the bonds that hold the particle 20 in place. By continuously shifting the direction of force, the system 100 prevents the particle 20 from settling back into a stable state of adhesion, thereby facilitating its eventual detachment. In addition, the use of multiple beams 14 ensures that the applied forces are distributed evenly across the particle 20's surface. This is important for preventing particle 20 from tilting or moving unpredictably during the detachment process. By balancing the forces, the system 100 ensures that the torsional effect is effective regardless of the particle's shape or surface characteristics. Furthermore, the alternating nature of the torsional forces helps to gradually weaken the adhesion without causing damage to the underlying semiconductor surface 30. Unlike high-intensity linear forces, which can potentially damage sensitive materials, the distributed and alternating nature of the torsional forces ensures a gentle but effective removal process.

The adaptive phase modulation of the laser beams is central to achieving effective torsional manipulation. The control unit 150, in combination with the AOI system 140, monitors the position and status of the particles 20 throughout the cleaning process. Based on real-time feedback, the control unit 150 dynamically adjusts the phase of each beam 14 to optimize the torsional forces being applied.

For example, if the AOI system 140 detects that a particle 20 is not responding as expected to the current phase modulation, the control unit 150 can alter the phase shifts to increase the torsional force or change the direction of rotation. This adaptive approach ensures that each particle receives the exact amount of force required to overcome its specific adhesion characteristics, resulting in a highly efficient cleaning process.

The use of real-time feedback from the AOI system 140 is a significant advantage of the present disclosure. The AOI system 140 continuously monitors the position, movement, and status of the particles 20. This data is relayed to the control unit 150, which uses it to make real-time adjustments to the laser beam parameters, including phase, intensity, and direction. The synchronization between the AOI system 140 and the control unit 150 ensures that the torsional forces are always optimally aligned with the particle 20's position and adhesion state. This real-time adjustment capability is particularly important for dealing with particles of different sizes, shapes, and adhesion strengths, which may require different force profiles to achieve effective detachment.

The shearing effect created by the torsional forces is key to weakening the adhesion between the particle and the semiconductor surface. By rotating the particle 20 back and forth, the torsional forces introduce stress at the interface between the particle 20 and the surface 30. This stress works to break the physical and chemical bonds holding the particle 20 in place. The alternating clockwise and counterclockwise movements create a dynamic environment that prevents the adhesion forces from stabilizing. The constant change in direction means that the bonds are continuously subjected to opposing forces, which weakens them over time. This process is much more effective at reducing adhesion than static or unidirectional forces, which often allow the particle 20 to adapt and resist detachment.

Once the torsional forces have sufficiently weakened the adhesion forces, the particle 20 is ready for removal. At this stage, the control unit 150 coordinates with the airflow generation unit 160 to apply an airstream that physically dislodges the particle 20 from the semiconductor surface 30. The airstream is directed in a controlled manner to ensure that the loosened particle 20 is completely removed from the work area, thereby preventing recontamination.

The combination of torsional manipulation and airflow removal provides a highly effective solution for cleaning semiconductor surfaces. The torsional forces ensure that the particle 20 is fully detached, while the airflow ensures that the detached particle is removed from the environment, leaving behind a clean surface ready for further processing.

In addition to the hardware components described above, the present disclosure contemplates the implementation of instructions and control algorithms in one or more non-transitory computer-readable media. The control unit 150, for example, can be configured to execute software or firmware instructions stored on such media to perform various control and monitoring functions described herein. By integrating these instructions into the system 100, dynamic and adaptive manipulation of particles on a semiconductor surface can be achieved in real-time.

A non-transitory computer-readable medium may include, by way of example, an electronic, magnetic, optical, electromagnetic, or semiconductor-based storage device. Suitable examples include, without limitation, read-only memory (ROM), random-access memory (RAM), electrically erasable programmable read-only memory (EEPROM), flash memory, or other solid-state memory technology, as well as optical storage media such as a CD-ROM or DVD, and magnetic storage devices such as a hard disk or tape.

The instructions stored on the non-transitory computer-readable medium may be executed by the control unit 150 to carry out steps such as:
1. Receiving and processing real-time particle detection data from the AOI system 140, including particle position, adhesion characteristics, and size;
2. Dynamically adjusting the phase, intensity, and angle of the plurality of individually controllable laser beams generated by the spatial light modulator 130, in response to particle information;
3. Implementing algorithms to apply torsional forces by inducing alternating clockwise and counterclockwise rotations of the target particle 20;
4. Coordinating the timing and parameters of the airflow generation unit 160 once the adhesion forces have been weakened, ensuring that particles are effectively removed without damaging the semiconductor surface 30; and
5. Storing or logging historical process data, feedback signals, and adjustment parameters for quality control, diagnostic, or iterative optimization purposes.

By utilizing a non-transitory computer-readable medium to store and execute these instructions, the system 100 can be flexibly updated or reprogrammed to accommodate different particle types, semiconductor surface materials, or cleaning protocols. Additionally, the software-driven approach enables seamless integration of new functionalities, improved particle manipulation algorithms, or enhanced imaging capabilities as advancements in AOI systems or spatial light modulators become available. This flexibility ensures that the disclosed system remains versatile, easily upgradable, and well-suited for evolving semiconductor manufacturing needs.

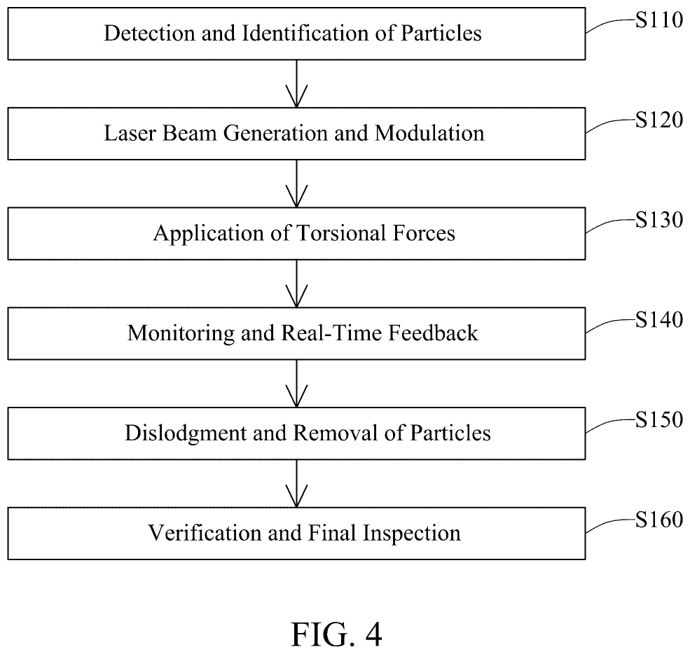

Refer to FIG. 4, which illustrates a flowchart of an embodiment of the cleaning method described in the present disclosure. The method for detaching particles from semiconductor surfaces described in the present disclosure provides a systematic approach for removing particles 20 from semiconductor surfaces 30. The following content outlines the sequential steps involved in the method, providing a comprehensive explanation of the process.

### Step S110: Detection and Identification of Particles

The AOI system 140 is utilized to scan the semiconductor surface 30 and identify particles 20. The AOI system 140 captures high-resolution images and analyzes them to determine the position and size of each particle 20 as well as the adhesion characteristics and orientation of the particles 20. Next, the collected data is relayed to the control unit 150 for processing and adaptive control of subsequent steps.

### Step S120: Laser Beam Generation and Modulation

The laser source 110 is activated to emit a coherent laser beam 10. Then the laser beam 10 is expanded using the beam expander 120 to ensure adequate power density for generating multiple beams14. The expanded laser beam 12 is past through the spatial light modulator 130, which divides it into multiple beams 14. Each beam 14 is directed to a specific location on the identified particles and modulated to control its phase, intensity, and angle for optimal torsional force application.

### Step S130: Application of Torsional Forces

The torsional forces by applying alternating clockwise and counterclockwise rotations to the particles 20 are generated. Next, the phase of beams 14 is adjusted using the control unit 150 to induce rotational forces. Then the torsional force profile is continuously adapted based on real-time feedback from the AOI system 140. These forces weaken the adhesion forces (e.g., van der Waals forces or electrostatic forces) between the particles 20 and the semiconductor surface 30.

### Step S140: Monitoring and Real-Time Feedback

Continuously monitor the process using the AOI system 140, which tracks the position and status of the particles 20 during torsional manipulation, provides feedback to the control unit 15 to dynamically adjust the laser beam parameters, typically within a few milliseconds, and ensures that the torsional forces are effectively loosening the particles 20.

### Step S150: Dislodgment and Removal of Particles

Once the particles 20 are sufficiently loosened, the airflow generation unit 160 is activated to direct a controlled airstream to the target area to dislodge the particles 20, adjust the velocity, pressure, and angle of the airflow based on feedback from the AOI system 140, and ensuring that dislodged particles 20 are blown away from the semiconductor surface 30 and captured by particle collection mechanisms 162 (e.g., filters or vacuum systems) to prevent recontamination.

### Step S160: Verification and Final Inspection

A final scan of the semiconductor surface using the AOI system 140 is performed a to verify complete removal of all identified particles and absence of residual contamination or damage to the semiconductor surface 30. If residual particles are detected, repeat the relevant steps to ensure thorough cleaning.

The present disclosure provides a versatile cleaning solution that is applicable across a range of different scenarios within semiconductor manufacturing. This section offers several practical use cases and examples to illustrate how the described cleaning system can be employed effectively to remove particles from various semiconductor surfaces. The following use cases demonstrate the adaptability of the system 100 in handling diverse environments, particle types, and adhesion characteristics.

### Use Case 1: Photomask Cleaning

Photomasks are critical components in semiconductor lithography, and even minor contamination on their surface can lead to defects in the patterning process, affecting the overall yield and quality of semiconductor devices. The system 100 in the present disclosure can be effectively utilized to clean photomasks by removing submicron particles that adhere to the surface due to electrostatic or chemical forces.

In this use case, the spatial light modulator (SLM) is configured to generate multiple laser beams that create localized torsional forces on each detected particle. The AOI system 140 plays a key role in identifying contaminants with high accuracy, allowing the control unit to adaptively focus on each particle's location. Once the particles are sufficiently loosened, the airflow generation unit 160 removes them, ensuring that the photomask is restored to a contamination-free state without any damage to its delicate features.

### Use Case 2: Wafer Surface Preparation

Wafers used in semiconductor device manufacturing must be kept meticulously clean to ensure optimal deposition, etching, and lithography results. Particles on wafer surfaces can cause a range of issues, from electrical defects to mechanical instability in the resulting integrated circuits. The system 100 described here is particularly well-suited for removing such particles, especially in dry conditions where high-adhesion forces are common.

In the wafer cleaning scenario, the torsional forces generated by the laser beams are particularly effective in dealing with particles that are adhered through van der Waals forces. The real-time feedback provided by the AOI system 140 enables the control unit 150 to dynamically adjust the laser beam properties, including the phase and intensity, ensuring that even the most stubborn particles are effectively detached without damaging the wafer surface. The use of an adaptive airstream to dislodge the particles after torsional manipulation further enhances the effectiveness of the cleaning process.

Use Case 3: Removal of Metallic Residues from Process Chambers

During semiconductor manufacturing, metallic residues can accumulate within process chambers, adhering to surfaces and causing contamination issues. These residues are often challenging to remove due to their strong adhesion to chamber surfaces and the need to avoid abrasive cleaning techniques that could damage sensitive components.

The present disclosure can be employed to remove metallic particles from sensitive areas within process chambers. The system 100, in combination with the spatial light modulator 130, generates torsional forces to gradually weaken the chemical bonds holding the metallic particles in place. By utilizing alternating clockwise and counterclockwise movements, the invention minimizes the risk of redepositing the metallic residues on other areas. The application of a controlled airstream then ensures that the dislodged particles are removed effectively, without leaving behind any residual contaminants.

### Use Case 4: Cleaning of MEMS Devices

Micro-Electro-Mechanical Systems (MEMS) devices often have complex geometries with micro-scale mechanical components that can easily become contaminated during the manufacturing process. The intricate structures of MEMS devices make traditional mechanical cleaning methods impractical, as they can cause damage or interference with sensitive moving parts.

The described system 100 is ideal for MEMS devices, as the non-contact torsional forces generated by the laser beams allow for precise manipulation of particles without direct contact with the device. The AOI system 140's real-time feedback ensures that even small contaminants lodged in complex geometries can be effectively targeted and removed. This non-contact method preserves the integrity and functionality of MEMS components while ensuring that all contaminants are dislodged and removed.

The described invention offers significant versatility in its application across different semiconductor manufacturing scenarios. Whether dealing with photomasks, wafers, MEMS devices, or process chambers, the system's ability to generate torsional forces and utilize real-time feedback provides an adaptable and effective solution for removing particles of varying sizes and adhesion characteristics. The non-contact approach ensures that sensitive surfaces and components are protected from damage, while the use of airflow for final removal guarantees a clean and contamination-free workspace, critical for achieving high-quality semiconductor products.

Although the disclosure has been disclosed and illustrated with reference to particular embodiments, the principles involved are susceptible for use in numerous other embodiments that will be apparent to a person having ordinary skill in the art. This disclosure is, therefore, to be limited only as indicated by the scope of the appended claims.

What is claimed is:

1. A system for removing particles from a semiconductor surface in a dry environment, the system comprising:
a laser source configured to emit a coherent laser beam;
a beam expander optically coupled to the laser source and configured to expand the coherent laser beam;
a spatial light modulator configured to receive the expanded laser beam and to divide said expanded laser beam into a plurality of individually controllable beams, each beam being modulated in at least one of phase, intensity, or angle; wherein the spatial light modulator is further configured to focus each of the plurality of individually controllable beams at distinct locations on a target particle disposed on the semiconductor surface, thereby forming a corresponding plurality of optical tweezers;
a control unit operably connected to the spatial light modulator, the control unit being configured to:
receive feedback data indicative of at least particle position or particle adhesion characteristics; and
adjust at least one of the phase, intensity, or angle of each of the plurality of beams to induce torsional forces on the target particle by alternately imparting rotational motion in clockwise and counterclockwise directions, thereby weakening adhesion forces between the target particle and the semiconductor surface;
an AOI system configured to detect the position or presence of the target particle on the semiconductor surface and provide the feedback data to the control unit; and
an airflow generation unit configured to generate a controlled airflow directed toward the semiconductor surface to remove the target particle after its adhesion is sufficiently reduced by the torsional forces.

2. The system of claim 1, wherein the spatial light modulator is a liquid crystal spatial light modulator configured to independently control the phase of each of the plurality of individually controllable beams.

3. The system of claim 1, wherein the control unit is further configured to adjust the intensity of at least one of the plurality of beams based on the feedback data indicating particle size or adhesion characteristics.

4. The system of claim 1, wherein the AOI system comprises a high-resolution imaging sensor selected from a CCD camera or a CMOS camera and is configured to generate real-time positional data of multiple particles.

5. The system of claim 1, wherein the airflow generation unit is adjustable in at least one of velocity, pressure, or direction, and wherein the control unit coordinates the airflow parameters based on the feedback data from the AOI system to ensure efficient removal of loosened particles.

6. The system of claim 1, further comprising a particle collection mechanism downstream of the airflow path to capture removed particles and prevent recontamination of the semiconductor surface.

7. A method of removing a particle adhered to a semiconductor surface in a dry environment, the method comprising:
(a) detecting, via an AOI system, the presence and position of at least one particle on the semiconductor surface;
(b) generating a coherent laser beam using a laser source and expanding the coherent laser beam with a beam expander;
(c) dividing the expanded laser beam, via a spatial light modulator, into a plurality of individually controllable beams, each beam being configurable in at least one of phase, intensity, or angle;
(d) directing the plurality of individually controllable beams onto distinct regions of the particle to form multiple optical tweezers that engage the particle at different points on its surface;
(e) applying torsional forces to the particle by modulating the phase of at least a subset of the beams to induce alternating clockwise and counterclockwise rotational motion of the particle, thereby progressively weakening adhesion forces between the particle and the semiconductor surface;
(f) monitoring, via feedback from the AOI system, the particle's position, orientation, or adhesion state and adjusting, in real time, beam parameters via a control unit to optimize particle detachment; and
(g) after the adhesion is sufficiently reduced, directing a controlled airflow over the semiconductor surface to dislodge and remove the particle without causing damage to the surface.

8. The method of claim 7, wherein adjusting beam parameters in step (f) comprises altering the relative phase of at least two of the plurality of beams to enhance the torsional effect on the particle.

9. The method of claim 7, wherein applying torsional forces in step (e) further comprises incrementally adjusting the beam angles to ensure that rotational forces are evenly distributed across the particle's surface.

10. The method of claim 7, wherein the AOI system provides positional accuracy sufficient to track submicron particles, and the feedback loop between the AOI system and the control unit ensures adaptive adjustment of beam parameters within milliseconds.

11. The method of claim 7, further comprising a verification step after particle removal, wherein the AOI system rescans the semiconductor surface to confirm the absence of residual contaminants and, if necessary, repeating steps (b) through (g) until the surface is substantially free of particles.

12. The method of claim 7, wherein the torsional forces are applied to weaken adhesion forces including at least one of van der Waals forces or electrostatic interactions.

13. The method of claim 7, wherein the semiconductor surface comprises a photomask, wafer, process chamber surface, or MEMS device, and the torsional removal technique is adapted by the control unit for the specific surface geometry or material characteristics.

14. A non-transitory computer-readable medium storing instructions that, when executed by a control unit in the system of claim 1, cause the control unit to:
(a) receive image data from the AOI system indicative of particle presence and characteristics;
(b) dynamically adjust at least one of the phase, intensity, or angle of each of the plurality of individually controllable beams to generate torsional forces on the particle; and
(c) coordinate the activation of the airflow generation unit once adhesion forces are sufficiently diminished to remove the particle from the semiconductor surface.
